(19) United States
(12) Patent Application Publication
(10) Pub. No.: US 2008/0122056 A1
(43) Pub. Date: May 29, 2008

(54) Semiconductor device package

(75) Inventors: Shle-Ge Lee, Seoul (KR); Dong-Kil Shin, Hwaseong-gun (KR); Min-Young Son, Asan-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/983,451

(22) Filed: Nov. 9, 2007

(30) Foreign Application Priority Data
Nov. 9, 2006 (KR) 10-2006-0110611

(51) Int. Cl. H01L 23/488

(52) U.S. Cl. 257/680; 257/E23.026

(57) ABSTRACT

Provided is a semiconductor device package comprising a printed circuit board, the printed circuit board including a window at a central portion and a connection part, a semiconductor chip including center-type bonding pads, wherein the semiconductor chip is mounted on an upper surface of the printed circuit board such that the center-type bonding pads are exposed by the window, bonding wires electrically connecting the center-type bonding pads with the printed circuit board through the window, a lower molding material at a lower surface of the printed circuit board, the lower molding material encapsulating the center-type bonding pads and the bonding wires, and an upper molding material encapsulating the semiconductor chip and the upper surface of the printed circuit board, wherein the lower molding material and the upper molding material are connected to each other through the connection part of the printed circuit board.

### CROSS-REFERENCE TO RELATED APPLICATIONS

This U.S. non-provisional patent application claims priority under 35 U.S.C. § 119 of Korean Patent Application No. 10-2006-0110611, filed in the Korean Intellectual Property Office on Nov. 9, 2006, the entire contents of which are hereby incorporated by reference.

### BACKGROUND OF THE INVENTION

1. Field of the Invention

The present invention disclosed herein relates to a semiconductor device package, and more particularly, to a board-on-chip package.

2. Description of the Related Art

Various semiconductor device packaging technologies are required to achieve high integration of semiconductor devices and miniaturization and multi-function of electronic equipments. Particularly, bare-chip mounting may be used as high-density mounting, which may be utilized for a special purpose that requires high performance. However, the bare-chip mounting has many limitations in quality, establishment and standardization of mounting technology, and reliability after mounting.

One of the semiconductor device packages developed to cope with those limitations is a ball grid array package (BGA package). The BGA package is a high-density surface-mount package that uses a printed circuit board (PCB) instead of a lead frame, and thus does not require external leads. The BGA package includes ball-shaped protruding terminals on an entire lower surface of a semiconductor device package. As the number of input/output terminals of a semiconductor device has increased, the BGA package is increasingly used.

In a conventional structure of the BGA package, solder balls are used as connection terminals that electrically connect a semiconductor chip with a system board, instead of using leads. Examples of the BGA package include a ceramic BGA (CBGA) package, a plastic BGA (PBGA) package, a tape BGA (TBGA) package, a metal BGA (MBGA) package, and a fine pitch BGA (FBGA) package.

FIG. 1A is a plan view for illustrating a conventional semiconductor device package. FIGS. 1B and 1C are cross-sectional views taken along lines I-I′ and II-II′ of FIG. 1A, respectively.

Referring to FIGS. 1A through 1C, a semiconductor device package includes a semiconductor chip 10, a printed circuit board (PCB) 30, bonding wires 45, a lower molding material 501, an upper molding material 50u, and solder balls 60.

The semiconductor chip 10 may include center-type bonding pads 12 at a central portion of an active region. The semiconductor chip 10 is mounted on an upper surface of the PCB 30 by using an adhesive material 35.

The PCB 30 includes an elongated window 21 at a central portion. The window 21 exposes center-type bonding pads 12 of the semiconductor chip 10. The PCB 30 includes a core material 20 serving as a main body, an upper insulation layer pattern 24u, metal line layers 22, and a lower insulation layer pattern 241 exposing the metal line layers 22 around the window 21. The upper and lower insulating layer patterns 24u and 24l are photo solder resist (PSR).

The bonding wires 45 electrically connect the center-type bonding pads 12 with the corresponding exposed metal line layers 22 through the window 21.

The lower molding material 501 encapsulates the center-type bonding pads 12 exposed by the window 21, the bonding wires 45, and a portion of a lower surface of the PCB 30 around the window 21. The portion of the lower surface of the PCB 30 includes the exposed metal line layers 22.

The upper molding material 50u encapsulates the semiconductor chip 10 and the upper surface of the PCB 30. The solder balls 60 are provided on the lower surface of the PCB 30 outside the lower molding material 501.

The solder balls 60 are connected to the metal line layers 22 of the PCB 30, and provide a connection with an external circuit such as a system board. The solder balls 60 protrude more than the lower molding material 501 so as to be mounted on, for example, the system board. A reference numeral 45b refers to connection balls formed during a wire bonding process for electrically connecting the center-type bonding pads 12 with the corresponding exposed metal line layers 22.

In such a board on chip (BOC) type semiconductor device package, adhesion between different kinds of materials is made, for example, between an upper molding material and a semiconductor chip, between the upper molding material and an adhesive material, between the upper molding material and an upper insulation layer pattern, between a lower molding material and a lower insulation layer pattern, and between the adhesive material and the upper insulation layer pattern. Thus, possibilities of mechanical and electrical defects may increase according to a fabrication process, a transfer process, and a user environment of the semiconductor device package. The mechanical and electrical defects occur due to thermal and physical stress caused by a difference in coefficient of thermal expansion (CTE) between those different kinds of materials. The mechanical and electrical defects caused due to the thermal and physical stress may occur at several portions of the semiconductor device package. Particularly, defects such as delamination may easily occur between the upper molding material and the upper insulating layer pattern because of the high vulnerability to the thermal and physical stress therebetween. Such defects, for example, the delamination between the upper molding material and the upper insulation layer pattern, may cause defective wire bonding at the central portion of the semiconductor device package.

### SUMMARY OF THE INVENTION

The present invention provides a semiconductor device package capable of preventing delamination between a molding material and a printed circuit board.

In accordance with an aspect of the present invention, a semiconductor device package comprises a printed circuit board, the printed circuit board including a window at a central portion and at least one connection part; a semiconductor chip including center-type bonding pads, wherein the semiconductor chip is mounted on an upper surface of the printed circuit board such that the center-type bonding pads are exposed by the window; bonding wires electrically connecting the center-type bonding pads with the printed circuit board through the window; a lower molding material at a lower surface of the printed circuit board, the lower molding material encapsulating the center-type bonding pads and the bonding wires; and an upper molding material encapsulating the semiconductor chip and the upper surface of the printed circuit board. The lower molding material and the upper molding material are connected to each other through the at least one connection part of the printed circuit board.

In an embodiment, the semiconductor device package further comprises solder balls at the lower surface of the printed circuit board outside the lower molding material.

In an embodiment, the lower molding material and the upper molding material include the same material. The lower molding material and the upper molding material can include an epoxy molding compound.

In an embodiment, the at least one connection part extends from the window, and protrudes from an edge of the semiconductor chip. In another embodiment, the at least one connection part partially overlaps the window, and protrudes from the edge of the semiconductor chip. The at least one connection part can partially overlap the semiconductor chip and be spaced apart from the window. The at least one connection part can have a closed 2-dimensional shape. The at least one connection part can be spaced apart from the window and an edge of the semiconductor chip. The at least one connection part can have a closed 2-dimensional shape.

In another embodiment, the at least one connection part has an open 2-dimensional shape.

In accordance with another aspect of the present invention, a method of forming a semiconductor device package comprises forming a window at a central portion of a printed circuit board and at least one connection part in the printed circuit board; mounting a semiconductor chip including center-type bonding pads on an upper surface of the printed circuit board such that the center-type bonding pads are exposed by the window; electrically connecting the center-type bonding pads with the printed circuit board through the window using bonding wires; providing a lower molding material at a lower surface of the printed circuit board, the lower molding material encapsulating the center-type bonding pads and the bonding wires; providing an upper molding material to encapsulate the semiconductor chip and the upper surface of the printed circuit board; and connecting the lower molding material and the upper molding material to each other through the at least one connection part of the printed circuit board.

In an embodiment, the method further comprises providing solder balls at the lower surface of the printed circuit board outside the lower molding material.

In an embodiment, the lower molding material and the upper molding material include the same material. In one embodiment, the lower molding material and the upper molding material are an epoxy molding compound.

In an embodiment, the at least one connection part extends from the window and protrudes from an edge of the semiconductor chip. The at least one connection part can partially overlap the window and protrude from the edge of the semiconductor chip.

In an embodiment, the at least one connection part partially overlaps the semiconductor chip and is spaced apart from the window. In one embodiment, the at least one connection part has a closed 2-dimensional shape.

In an embodiment, the at least one connection part is spaced apart from the window and an edge of the semiconductor chip. The at least one connection part can have a closed 2-dimensional shape. In another embodiment, the at least one connection part can have an open 2-dimensional shape.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention.

FIG. 1A is a plan view illustrating a conventional semiconductor device package, and FIGS. 1B and 1C are cross-sectional views taken along lines I-I′ and II-II′ of FIG. 1A, respectively.

FIG. 2A is a plan view illustrating a semiconductor device package according to an embodiment of the present invention, and FIGS. 2B and 2C are cross-sectional views taken along lines III-III′ and IV-IV′ of FIG. 2A, respectively.

FIGS. 3 through 5 are plan views illustrating a semiconductor device packages according to other embodiments of the present invention.

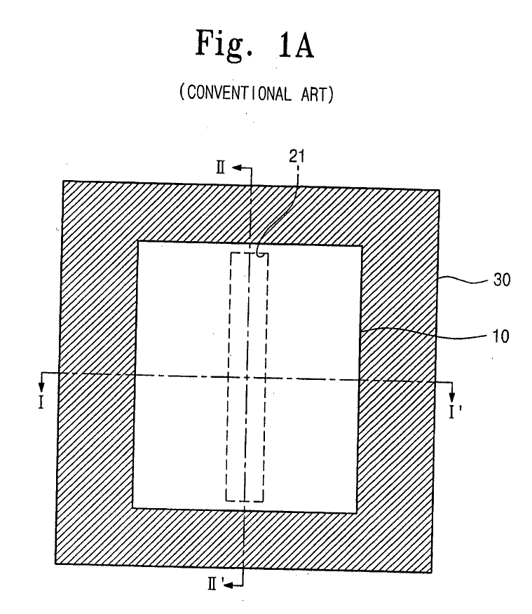

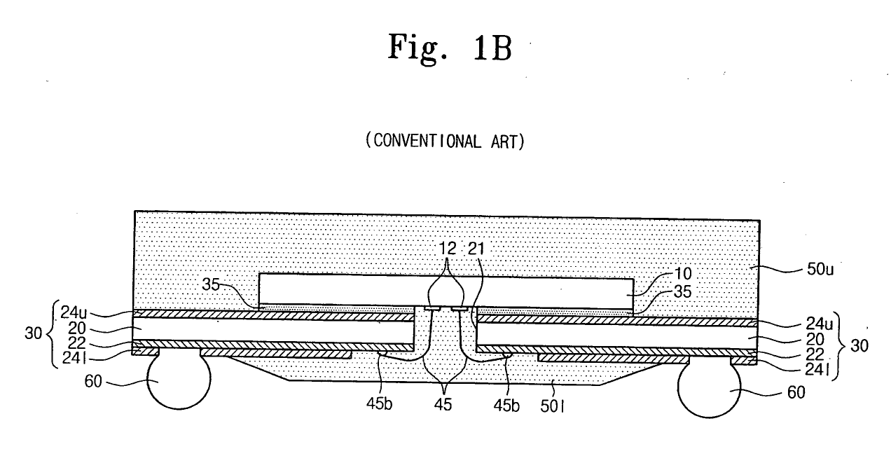

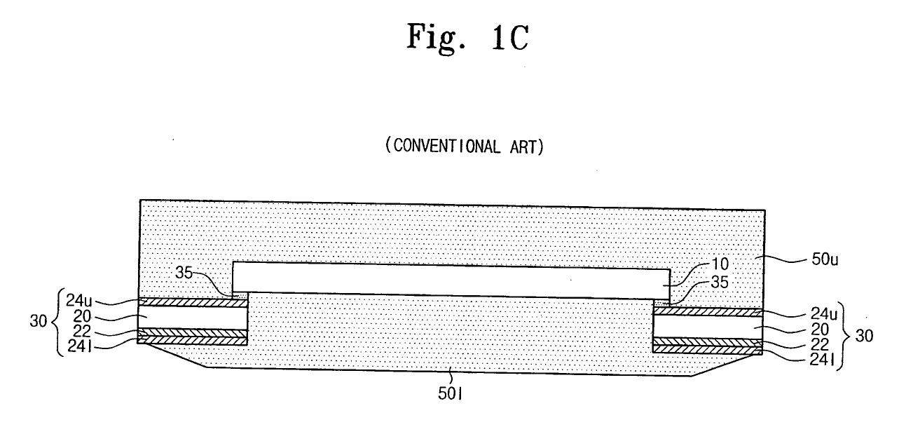

### DETAILED DESCRIPTION OF EMBODIMENTS

Embodiments of the present invention will be described below in more detail with reference to the accompanying drawings. The present invention may, however, be embodied in different forms and should not be constructed as limited to the embodiments set forth herein. Rather, these embodiments are provided so that this description will be thorough and complete, and will fully convey the scope of the present invention to those skilled in the art. In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present.

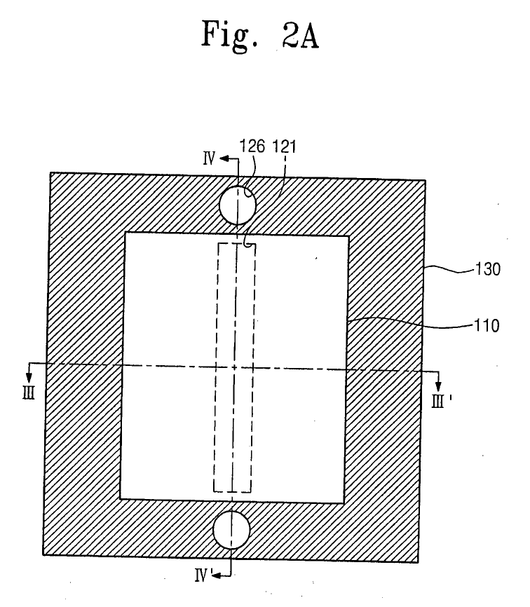

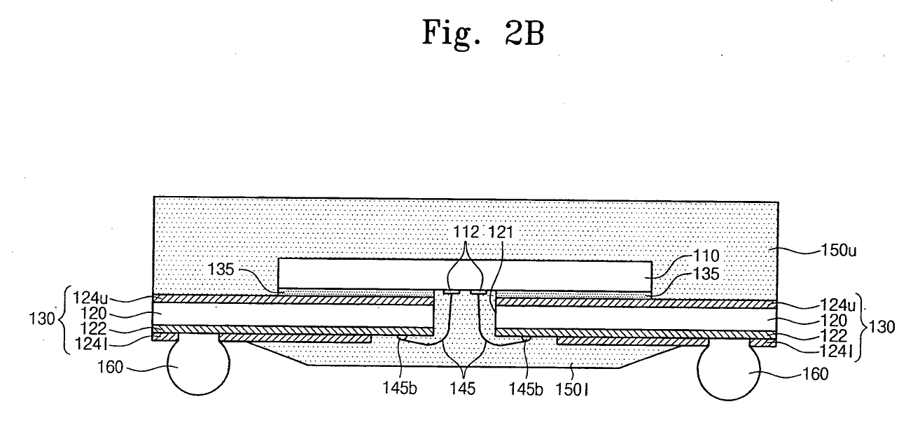

FIG. 2A is a plan view illustrating a semiconductor device package according to an embodiment of the present invention, and FIGS. 2B and 2C are cross-sectional views taken along lines III-III′ and IV-IV′, respectively.

Referring to FIGS. 2A through 2C, a semiconductor device package includes a semiconductor chip 110, a printed circuit board (PCB) 130, bonding wires 145, a lower molding material 150l, an upper molding material 150u, and solder balls 160.

The semiconductor chip 110 may include center-type bonding pads 112 at a central portion of an active region. The semiconductor chip 110 may be mounted on an upper surface of the PCB 130 by using an adhesive material 135.

The PCB 130 may include an elongated window 121 at a central portion. The window 121 may expose the center-type bonding pads 112 of the semiconductor chip 110. The PCB 130 may include a core material 120 serving as a main body, an upper insulation layer pattern 124u, metal line layers 122, and a lower insulation layer pattern 124l exposing the metal line layers 122 around the window 121. The upper and lower insulation layer patterns 124u and 124l may be photo solder resist (PSR).

Also, the PCB 130 may include one or more connection parts 126. The connection parts 126 may be spaced apart from the window 121 and an edge of the semiconductor chip 110 in a major axis direction of the window 121 of the PCB 130. Each connection part 126 may be a hole-type penetrating the PCB 130. The hole-type may have a closed 2-dimensional (2D) shape. Examples of the closed 2D shape may include a circular, triangular, or quadrangular shape.

The bonding wires 145 may electrically connect the center-type bonding pads 112 with the corresponding exposed metal line layers 122 through the window 121.

The lower molding material 150l may encapsulate the center-type bonding pads 112 exposed by the window 121, the bonding wires 145, and a portion of the lower surface of the PCB 130 around the window 121. The portion of the lower surface of the PCB 130 includes the exposed metal line layers 122. The lower molding material 150l may be an epoxy molding compound (EMC).

The upper molding material 150u may encapsulate the semiconductor chip 110 and the upper surface of the PCB 130. The upper molding material 150u may be the same material as the lower molding material 150l. Thus, the upper molding material 150u may be an epoxy molding compound.

Since the PCB 130 includes the connection parts 126, the lower molding material 150l and the upper molding material 150u may be connected to each other through the connection parts 126. Thus, compared to a conventional semiconductor device package, an adhesive force may be improved between the PCB 130 and the lower molding material 150l, and between the PCB 130 and the upper molding material 150u. Also, the connection between the lower molding material 150l and the upper molding material 150u may contribute to reducing the amount of deformation caused by different coefficients of thermal expansion (CTE) between materials around the connection parts 126. Furthermore, the amount of deformation caused due to the thermal and physical stress applied from the external may also be reduced. Accordingly, delamination can be prevented from occurring between the PCB 130 and the lower molding material 150l, and between the PCB 130 and the upper molding material 150u.

In an embodiment, the solder balls 160 can be provided on the lower surface of the PCB 130 outside the lower molding material 150l. In this embodiment, the solder balls 160 are connected to the metal line layers 122 of the PCB 130, thereby providing a connection with an external circuit such as a system board. The solder balls 160 may be formed thicker than the lower molding material 150l so as to be mounted on, for example, the system board. Connection balls 145b may be formed during a wire bonding process for electrically connecting the center-type bonding pads 112 with the corresponding exposed metal line layers 122.

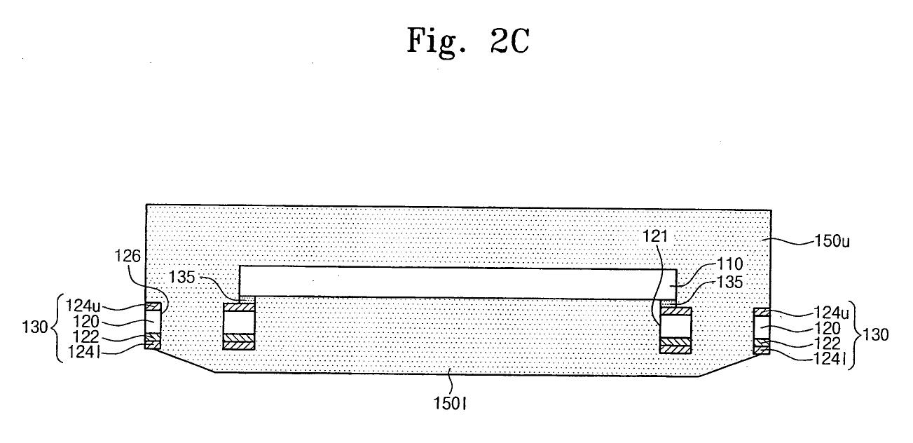

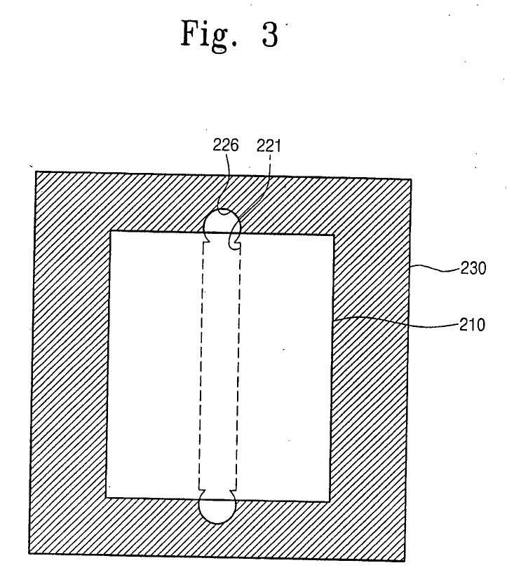

FIGS. 3 through 5 are plan views illustrating a semiconductor device packages according to other embodiments of the present invention.

FIG. 3 is a plan view prior to formation of an upper molding material (150u of FIGS. 2A and 2B) and a lower molding material (150l of FIGS. 2A and 2B) in a process of fabricating a semiconductor device package according to an embodiment. That is, FIG. 3 is an upper plan view of a PCB 130 on which a semiconductor chip 210 is mounted.

The semiconductor chip 210 may include center-type bonding pads (not shown) at a central portion of an active region. The semiconductor chip 210 may be mounted on an upper surface of the PCB 230 by using an adhesive material.

The PCB 230 may include an elongated window 221 at a central portion. The window 221 may expose center-type bonding pads of the semiconductor chip 210. The PCB 230 may include a core material serving as a main body, an upper insulation layer pattern (oblique pattern), metal line layers, and a lower insulation layer pattern exposing the metal line layers around the window 221. The upper and lower insulation layer patterns may be photo solder resist (PSR).

The PCB 230 may include at least one connection part 226. In one embodiment, the connection part 226 can extend from the window 221 and protrude from an edge of the semiconductor chip 210. In another embodiments the connection part 226 can partially overlap the window 221 and protrude from the edge of the semiconductor chip 210. The connection part 226 may be a hole-type penetrating the PCB 230. The hole-type may have an open 2D shape. The open 2D shape may be an open curve or an open polygon.

Since the PCB 230 includes the connection part 226, the lower molding material and the upper molding material can be connected together through the connection part 226 during a subsequent process. Thus, compared to a conventional semiconductor device package, an adhesive force may be improved between the PCB 230 and the lower molding material and between the PCB 230 and the upper molding material. Also, the connection between the lower molding material and the upper molding material can contribute to reducing the amount of deformation caused due to different coefficients of thermal expansion (CTE) between components around the connection part 226. Furthermore, the amount of deformation caused by thermal and physical stress from the external can also be reduced. Accordingly, delamination can be prevented from occurring between the PCB 230 and the lower molding material, and between the PCB 230 and the upper molding material.

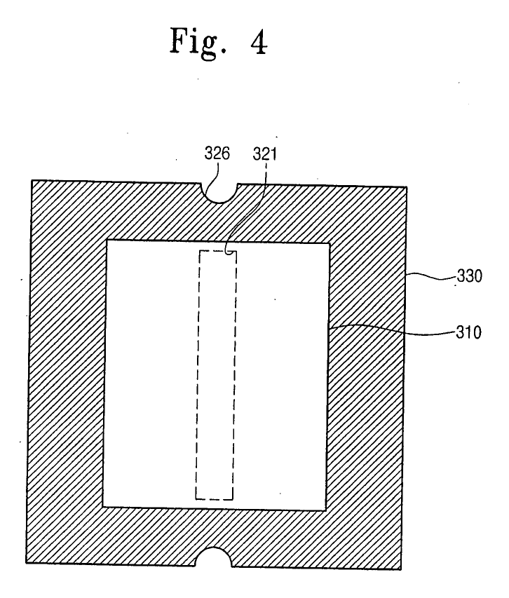

FIG. 4 is a plan view prior to formation of an upper molding material (150u of FIGS. 2A and 2B) and a lower molding material (150l of FIGS. 2A and 2B) in a process of fabricating a semiconductor device package according to another embodiment. That is, FIG. 4 is an upper plan view of a PCB 330 on which a semiconductor chip 310 is mounted.

The semiconductor chip 310 may include center-type bonding pads (not shown) at a central portion of an active region. The semiconductor chip 310 may be mounted on an upper surface of the PCB 330 by using an adhesive material.

The PCB 330 may include an elongated window 321 at a central portion. The window 321 may expose the center-type bonding pads of the semiconductor chip 310. The PCB 330 may include a core material serving as a main body, an upper insulation layer pattern (oblique pattern), metal line layers, and a lower insulation layer pattern exposing the metal line layers around the window 321. The upper and lower insulation layer patterns may be photo solder resist (PSR).

The PCB 330 may include one or more connection parts 326. The connection parts 326 may be spaced apart from the window 321 and an edge of the semiconductor chip 310 in a major axis direction of the window 321 of the PCB 330. The connection parts 326 may penetrate the PCB 330. The connection parts 326 may have an open 2D shape. The open 2D shape may be an open curve or an open polygon.

Since the PCB 330 includes the connection parts 326, the lower molding material and the upper molding material may be connected together through the connection parts 326 during a subsequent process. Accordingly, compared to a conventional semiconductor device package, an adhesive force may be improved between the PCB 330 and the lower molding material and between the PCB 330 and the upper molding material. Also, the connection between the lower molding material and the upper molding material may contribute to reducing the amount of deformation caused by different coefficients of thermal expansion (CTE) between components around the connection parts 326. Furthermore, the amount of deformation caused by thermal and physical stress from the external can also be reduced. Accordingly, delamination may be prevented from occurring between the PCB 330 and the lower molding material and between the PCB 330 and the upper molding material.

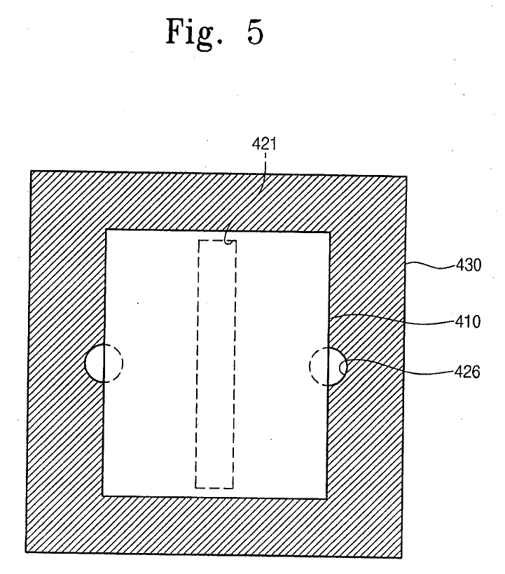

FIG. 5 is a plan view prior to formation of an upper molding material (150u of FIGS. 2A and 2B) and a lower molding material (150l of FIGS. 2A and 2B) in a process of fabricating a semiconductor device package according to another embodiment. That is, FIG. 5 is an upper plan view of a PCB 430 on which a semiconductor chip 410 is mounted.

The semiconductor chip 410 may include center-type bonding pads (not shown) at a central portion of an active region. The semiconductor chip 410 may be mounted on an upper surface of the PCB 430 by using an adhesive material.

The PCB 430 may include an elongated window 421 at a central portion. The window 421 may expose center-type bonding pads of the semiconductor chip 410. The PCB 430 may include a core material serving as a main body, an upper insulation layer pattern (oblique pattern), metal line layers, and a lower insulation layer pattern exposing the metal line layers around the window 421. The upper and lower insulation layer patterns may be photo solder resist (PSR).

The PCB 430 may include one or more connection parts 426. The connection parts 426 may be spaced apart from the window 421 in a minor axis direction of the window 421 of the PCB 430, and partially overlap the semiconductor chip 410. The connection parts 426 may be a hole-type penetrating the PCB 430. The hole-type may have a closed 2D shape. Examples of the closed 2D shape may include a circle, a triangle, or a quadrangle.

Since the PCB 430 includes the connection parts 426, the lower molding material and the upper molding material may be connected together through the connection parts 426. Thus, compared to a conventional semiconductor device package, an adhesive force can be improved between the PCB 430 and the lower molding material, and between the PCB 430 and the upper molding material. Also, the connection between the lower molding material and the upper molding material may contribute to reducing the amount of deformation caused by different coefficients of thermal expansion (CTE) between components around the connection part 426. Furthermore, the amount of deformation caused due to thermal and physical stress from the external can also be reduced. Accordingly, delamination may be prevented from occurring between the PCB 430 and the lower molding material and between the PCB 430 and the upper molding material.

A semiconductor device package according to an embodiment of the present invention includes a PCB including a connection part that connects an upper molding material with a lower molding material. Thus, the PCB and the molding materials of the semiconductor device package are not delaminated from each other even if thermal and physical stress is applied thereto from the external. Accordingly, the semiconductor device package may achieve high thermal, physical, and electrical reliability.

As described previously, a semiconductor device package according to the present invention includes a PCB including at least one connection part for connecting an upper molding material with a lower molding material. Thus, delamination can be prevented from occurring between the PCB and the molding materials by thermal and physical stress applied from the external. Accordingly, the semiconductor device package may achieve high thermal, physical, and electrical reliability.

While the example embodiments of the present invention and its advantages have been described in detail, it should be understood that various changes, substitutions and alterations can be made herein without departing from the scope of the invention as defined by appended claims.

What is claimed is:

1. A semiconductor device package comprising:
a printed circuit board, the printed circuit board including a window at a central portion and a connection part;
a semiconductor chip including center-type bonding pads, wherein the semiconductor chip is mounted on an upper surface of the printed circuit board such that the center-type bonding pads are exposed by the window;
bonding wires electrically connecting the center-type bonding pads with the printed circuit board through the window;
a lower molding material at a lower surface of the printed circuit board, the lower molding material encapsulating the center-type bonding pads and the bonding wires; and
an upper molding material encapsulating the semiconductor chip and the upper surface of the printed circuit board, wherein the lower molding material and the upper molding material are connected to each other through the connection part of the printed circuit board.

2. The semiconductor device package of claim 1 further comprising solder balls at the lower surface of the printed circuit board outside the lower molding material.

3. The semiconductor device package of claim 1, wherein the lower molding material and the upper molding material include the same material.

4. The semiconductor device package of claim 3, wherein the lower molding material and the upper molding material include an epoxy molding compound.

5. The semiconductor device package of claim 1, wherein the connection part extends from the window and protrudes from an edge of the semiconductor chip.

6. The semiconductor device package of claim 5, wherein the connection part partially overlaps the window and protrudes from the edge of the semiconductor chip.

7. The semiconductor device package of claim 5, wherein the connection part partially overlaps the semiconductor chip and is spaced apart from the window.

8. The semiconductor device package of claim 7, wherein the connection part has a closed 2-dimensional shape.

9. The semiconductor device package of claim 5, wherein the connection part is spaced apart from the window and an edge of the semiconductor chip.

10. The semiconductor device package of claim 9, wherein the connection part has a closed 2-dimensional shape.

11. The semiconductor device package of claim 9, wherein the connection part has an open 2-dimensional shape.
